(19) United States
(12) Patent Application Publication
(10) Pub. No.: US 2005/0206011 A1
(43) Pub. Date: Sep. 22, 2005

(54) Circuit module

(76) Inventors: Eiju Maehara, Gunma (JP); Kenichi Kobayashi, Gunma (JP)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 11/082,125

(22) Filed: Mar. 16, 2005

(30) Foreign Application Priority Data
Mar. 17, 2004 (JP) 2004-076299

(51) Int. Cl. H01R 13/62; H01L 23/48

(52) U.S. Cl. 257/780

(57) ABSTRACT

The present invention is intended to miniaturize a circuit module including a pressure sensing element. In a circuit module of this embodiment, a laminated sheet to which a pressure sensing element and a circuit element are electrically connected is thinned and allowed to occupy as little space as possible. Thus, the entire circuit module is reduced in thickness and saving of space is realized. Moreover, noise caused by an electromagnetic wave, an electric field and the like is shut off by use of reinforcing plates. Thus, pressure information can be converted into accurate electric signals. Furthermore, noise to the outside from the circuit module of the present invention can be shut off.

Priority is claimed to Japanese Patent Application Number JP2004-076299 filed on Mar. 17, 2004, the disclosure of which is incorporated herein by reference in its entirety.

### BACKGROUND OF THE INVENTION

1. Field of the Invention

The present invention relates to a circuit module, and more particularly relates to a circuit module including an element which senses a pressure.

2. Description of the Related Art

With reference to FIGS. 6A and 6B, description will be given of a conventional circuit module including a pressure sensing element.

First, with reference to FIGS. 6A and 6B, a configuration of the conventional circuit module 100 will be described. FIG. 6A is a perspective view of the conventional circuit module 100, and FIG. 6B is a cross-sectional view thereof.

With reference to FIG. 6A, the circuit module 100 includes: a first substrate 130 having a pressure sensing element 122 fixed to its surface; and a second substrate 129 which is connected to the first substrate by means of connection terminals 128, and has a circuit element 123 fixed to its surface. This circuit module 100 is a module which converts an external force applied to the pressure sensing element 122 into an electric signal, and outputs the signal to the outside (see Patent Document 1).

With reference to FIG. 6B, a cross-sectional structure of the circuit module 100 will be described. In order to bear the external force applied to the pressure sensing element 122, a first reinforcing plate 124 and a second reinforcing plate 125 are closely attached to the surface of the first. substrate 130 and a rear surface thereof, respectively. In addition, the first and second substrates 130 and 129 are mechanically and electrically connected to each other by means of the connection terminals 128. Moreover, thicknesses of the first substrate 130, the first reinforcing plate 124 and the second reinforcing plate 125 add up to about 3 mm. This technology is described for instance in U.S. Pat. No. 5,521,596

However, a large space and a height are required to install the conventional circuit module including the pressure sensing element. Moreover, since the substrates are mechanically connected to each other by use of the connection terminals 128, there are problems of complex processing, costs, weight and the like.

### SUMMARY OF THE INVENTION

The present invention provides a circuit module that includes a laminated sheet including a first conductive pattern formed on a surface of an insulating film and a second conductive pattern formed on a rear surface of the insulating film, a pressure sensing element which is electrically connected to the first conductive pattern, and converts a pressure applied from the outside into an electric signal, a circuit element which is electrically connected to the first conductive pattern and is fixed to a surface of the laminated sheet, a first reinforcing plate which has a first opening in a spot where the pressure sensing element and the circuit element are provided, and covers the surface of the laminated sheet; and a second reinforcing plate which has a second opening so as to partially expose the second conductive pattern, and covers a rear surface of the laminated sheet.

The circuit module of the present invention includes the laminated sheet, the first and second reinforcing plates have through-holes in substantially the same spots, and the laminated sheet and the first and second reinforcing plates are integrally fastened by use of fastening means penetrating the through-holes.

The circuit module of the present invention includes the both reinforcing plates and the laminated sheet are closely attached to each other with insulation sheets interposed therebetween.

The circuit module of the present invention includes the first and second reinforcing plates are made of a conductive material.

The circuit module of the present invention includes any of the first and second reinforcing plates is connected to a ground potential through the conductive pattern.

The circuit module of the present invention includes the second conductive pattern exposed from the second opening functions as an external terminal.

The circuit module of the present invention includes the laminated sheet has flexibility.

According to the circuit module of the present invention, the first opening is provided in the first reinforcing plate for reinforcing the thin laminated sheet, and the circuit element is fixed to the surface of the laminated sheet exposed from the first opening. Therefore, an integrated small circuit module can be provided. Furthermore, by using substrates made of metal as the reinforcing plates, a shielding effect achieved by the reinforcing plates makes it possible to prevent adverse effects caused by noise.

### BRIEF DESCRIPTION OF THE DRAWINGS

FIG. 1A is a perspective view, FIG. 1B is a perspective view and FIG. 1C is a cross-sectional view showing a circuit module of an embodiment of the present invention.

FIG. 2 is a perspective view showing a method for manufacturing the circuit module of the embodiment.

FIG. 3 is a perspective view showing a method for manufacturing a circuit module of an embodiment.

FIGS. 4A to 4D are cross-sectional views showing a method for manufacturing a laminated sheet applied to the circuit module of the embodiment.

FIGS. 5A to 5D are cross-sectional views showing the method for manufacturing the laminated sheet applied to the circuit module of the embodiment.

FIG. 6A is a perspective view and FIG. 6B is a cross-sectional view showing a conventional circuit module.

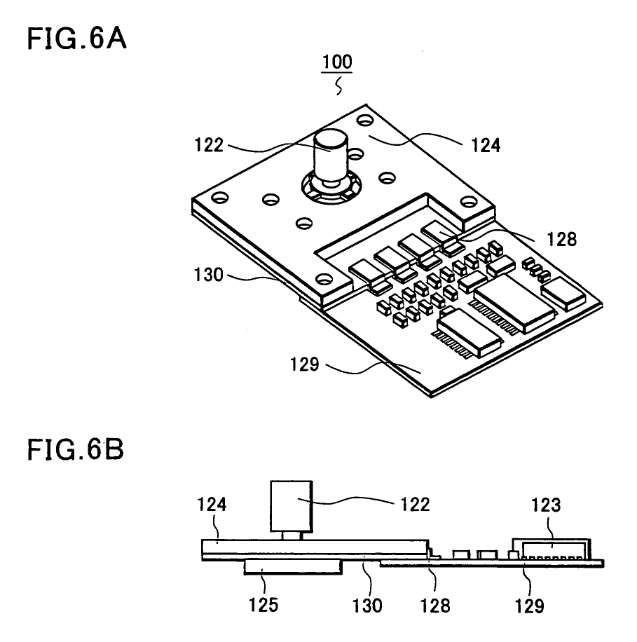

### DESCRIPTION OF THE EMBODIMENTS

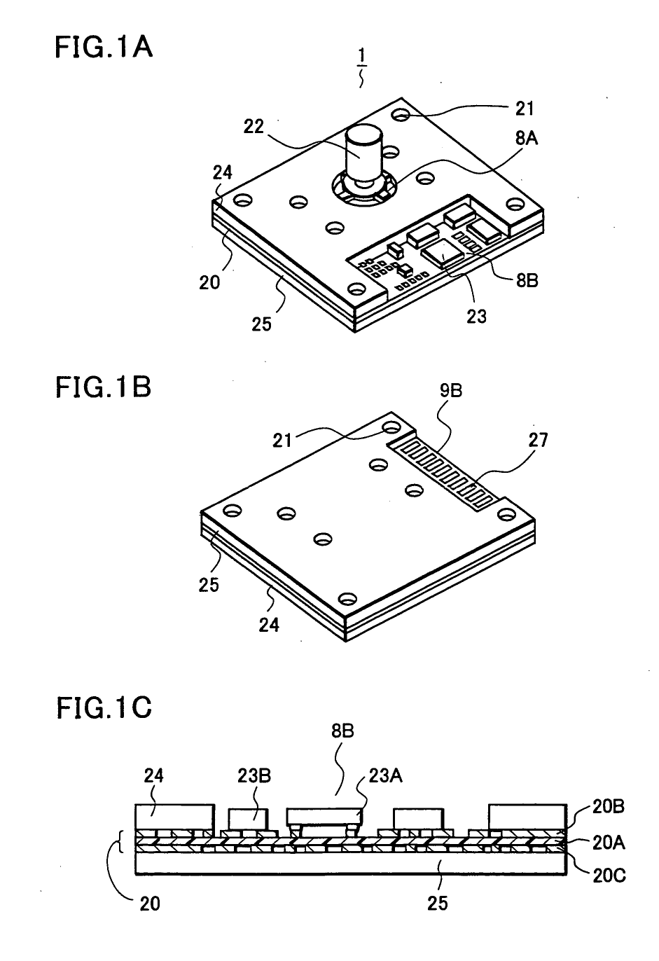

With reference to FIGS. 1A to 1C, description will be given of a configuration of a circuit module 1 according to an embodiment of the present invention. FIG. 1A is a perspective view of the circuit module 1 when viewed from above, FIG. 1B is a perspective view of the circuit module 1 when viewed from below, and FIG. 1C is a cross-sectional view around a first opening 8B.

With reference to FIG. 1A, the circuit module 1 of this embodiment has a configuration in which a laminated sheet 20 having conductive patterns on both sides thereof is sandwiched by a first reinforcing plate 24 and a second reinforcing plate 25.

With reference to FIG. 1A, in the laminated sheet 20, first conductive patterns are formed on a surface of an insulating film, and second conductive patterns are formed on a rear surface thereof. The laminated sheet 20 has a thickness of about 0.3 mm, and is very thin. Therefore, the laminated sheet 20 has an excellent flexibility and has a structure in which cracks or the like are unlikely to occur even if a bending stress acts thereon. The first conductive patterns formed in a surface of the laminated sheet 20 are exposed from first openings 8 provided in the first reinforcing plate 24. A pressure sensing element 22 and circuit elements 23 are fixed to the first conductive patterns exposed. In addition, the second conductive patterns formed in a rear surface of the laminated sheet 20 are exposed to the outside from a second opening provided in the second reinforcing plate 25. Moreover, the first and second conductive patterns are conducting through the insulating film. Furthermore, a multi-layered wiring structure including three layers or more may be formed in the laminated sheet 20.

The first and second reinforcing plates 24 and 25 play a role of mechanically supporting the above-described laminated sheet 20 by sandwiching the sheet from the both sides thereof. As a material of these reinforcing plates, metal, ceramic, resin or the like can be employed. Furthermore, the first and second reinforcing plates 24 and 25 and the laminated sheet 20 have connection holes 21 drilled in the same spots when planarly viewed. Accordingly, by fastening the first and second reinforcing plates 24 and 25 and the laminated sheet 20 by use of fastening means such as bolts, the plates and the sheet are held as a plate-like unit. If metal is used as the material of the first and second reinforcing plates 24 and 25, a shielding effect achieved by these reinforcing plates can prevent the circuit elements 23 from being adversely affected by noise from the outside. Furthermore, the shielding effect can be further improved by connecting the reinforcing plates to a ground potential through the conductive patterns of the laminated sheet.

The pressure sensing element 22 includes a plurality of resistors therein, and has a function of converting an external force, such as a pressure applied from the outside, into an electric signal. Moreover, the pressure sensing element 22 is firmly fixed to the laminated sheet 20 since the pressure or the like is applied thereto from the outside. Furthermore, after the pressure sensing element 22 is electrically connected to the conductive pattern, a connection part may be covered with resin to increase strength of connection with the conductive pattern. Moreover, the pressure sensing element may be connected near a center of the laminated sheet 20 in order to enable the pressure from the outside to be equally dispersed.

As the circuit elements 23, an active element and a passive element can be generally employed. To be more specific, as the active element, an LSI, an IC, a discrete transistor, a diode and the like can be used. Particularly, since the conductive patterns formed in the surface of the laminated sheet are minutely formed, a semiconductor element such as the LSI can be directly mounted face-down. Moreover, as the passive element described above, a chip resistor, a chip condenser and the like can be used. Furthermore, these circuit elements 23 may be electrically connected to the pressure sensing element 22. Moreover, a package in which the above-described active element or passive element is plastic molded can also be used as the circuit element 23.

With reference to FIG. 1B, by cutting off a part of the second reinforcing plate 25, the second opening 9B is provided. Connection patterns 27 formed of the second conductive patterns provided in the rear surface of the laminated sheet 20 are exposed to the outside from the second opening 9B. The connection patterns 27 function as input/output terminals of the entire module. Here, the second opening 9B having a rectangular shape is provided along a side of one of the reinforcing plates. Along a longitudinal direction of the opening 9B, a plurality of the connection patterns 27 are formed in line. Although, one second opening 9B is provided in FIG. 1B, it is also possible to provide a plurality of second openings 9B and to form the connection patterns 27 for the respective second openings 9B.

With reference to FIG. 1C, the circuit elements 23 are mounted on the first conductive patterns 20B exposed from the first opening 8B. Here, the circuit element 23A that is a semiconductor element is disposed face-down and connected to the first conductive pattern 20B by means of a bump electrode. Moreover, the circuit element 23B that is a chip element is fixed to the first conductive pattern 20B by means of a brazing material such as solder. Here, heights of the circuit elements 23 are set to be lower than that of a surface of the first reinforcing plate 24. Thus, the circuit elements 23 can be housed in the first opening 8B. Therefore, the entire circuit module can be formed to have a structure with few protrusions. Here, since a thickness of the first reinforcing plate 24 is, for example, about 1 mm, most kinds of the circuit elements 23 can be housed in a space of the first opening 8B.

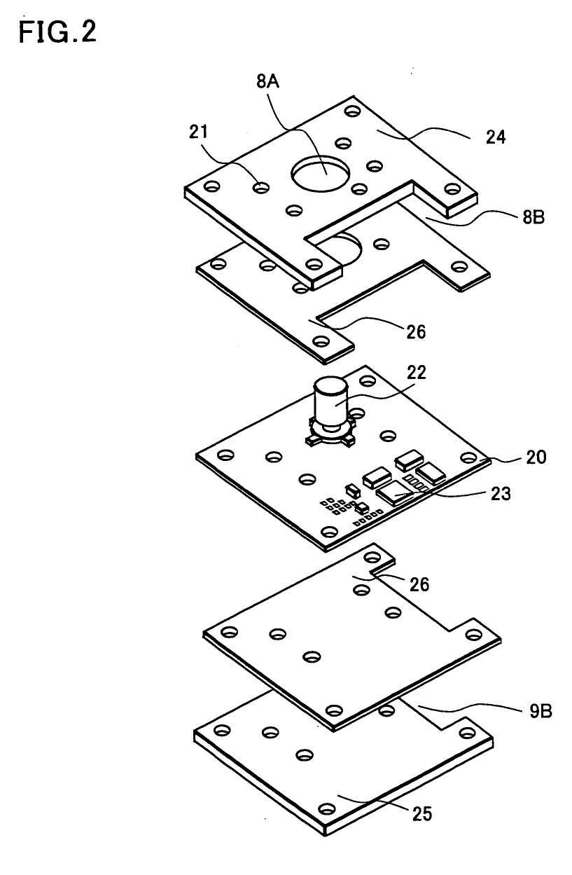

With reference to FIG. 2, constituent components of the circuit module 1 will be described more in detail. FIG. 2 is a perspective view showing a state where the constituent components of the circuit module 1 are disassembled.

The laminated sheet 20 is integrated with the first and second reinforcing plates with insulation sheets 26 interposed therebetween. These insulation sheets 26 have a function of insulating the conductive patterns formed in the both surfaces of the laminated sheet 20 from the reinforcing plates. Moreover, as the insulation sheets 26, sheets made of resin may be used. Furthermore, in the insulation sheets 26, openings corresponding to those in the first and second reinforcing plates are provided.

The first opening 8B provided in the first reinforcing plate 24 and the second opening 9B provided in the second reinforcing plate 25 are formed in different positions from each other when planarly viewed. To be more specific, although both of the openings are formed in peripheral portions of the reinforcing plates, the second opening 9B is formed in a side different from a side in which the first opening 8B is formed. Thus, a portion of the laminated sheet 20 to which the circuit elements 23 are fixed can be supported by the second reinforcing plate 25. Since the laminated sheet 20 of this embodiment is extremely thin, it is important in securing a mechanical strength to support a region having the circuit elements 23 fixed therein by use of the second reinforcing plate 25.

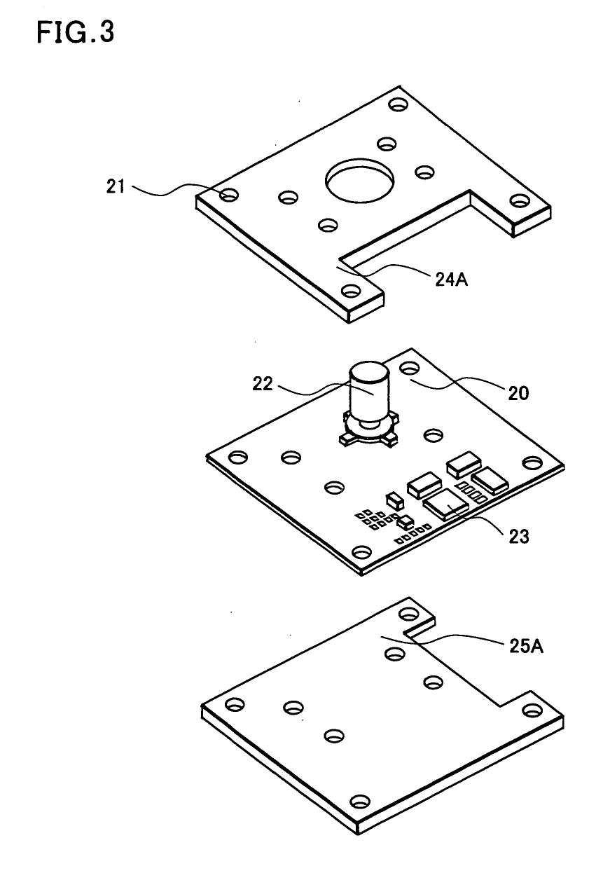

With reference to FIG. 3, a configuration of a circuit module of another embodiment will be described. In the configuration shown in FIG. 3, insulation sheets are omitted by using resin or ceramic that is a nonconductive material as a material of reinforcing plates. Therefore, a more simplified circuit module can be provided.

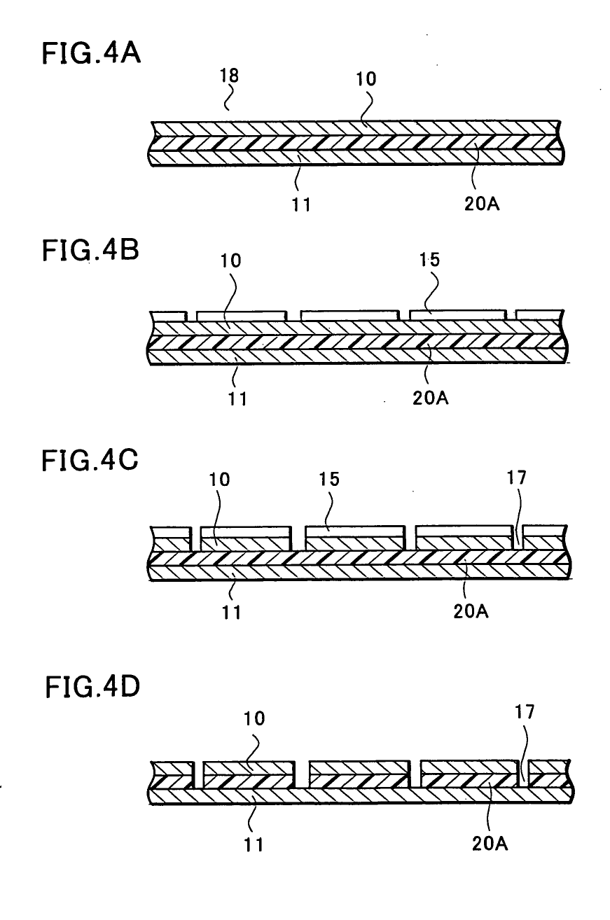

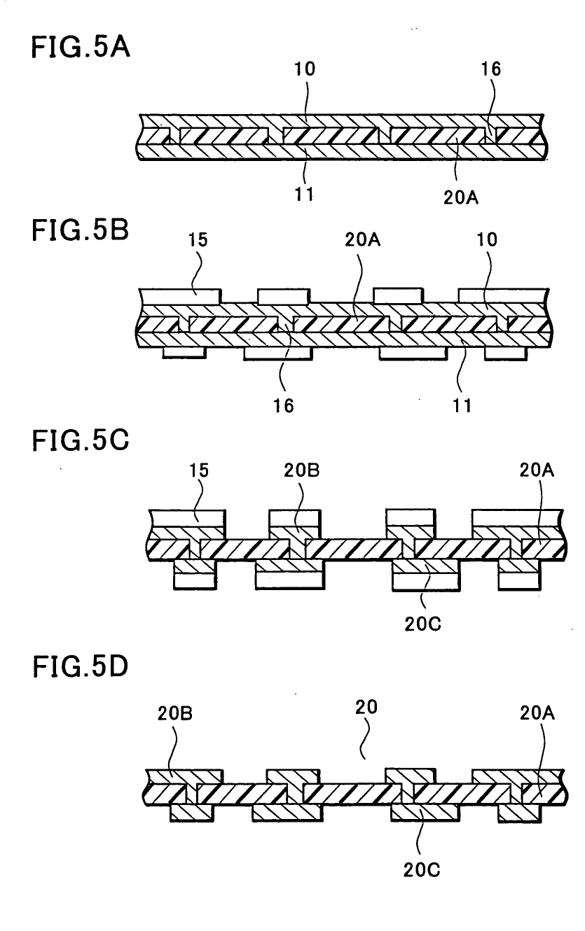

With reference to FIGS. 4 and 5, a method for manufacturing the above-described laminated sheet 20 will be described below.

First, as shown in FIG. 4A, an insulating resin sheet 18 in which a first conductive film 10 and a second conductive film 11 are attached to an insulating film 20A is prepared.

A surface of the insulating resin sheet 18 has the first conductive film 10 formed in substantially the entire region thereof, and a rear surface thereof has the second conductive film 11 formed in substantially the entire region thereof. Moreover, the insulating film 20A is formed of an insulating material made of polymers such as polyimide resin or epoxy resin. Moreover, the first and second conductive films 10 and 11 may be formed of a material mainly made of Cu or a heretofore known lead frame material.

The insulating film 20A may be polyimide resin, epoxy resin or the like. In the case of a casting method in which paste resin is applied to form a sheet, a film thickness thereof is about 10 μm to 100 μm. In addition, in the case of forming the film as a sheet, a commercially available film has a minimum thickness of 25 μm. Moreover, a filler may be mixed in the film in consideration for thermal conductivity.

Next, as shown in FIG. 4B, after a photoresist 15 is applied to the entire surface of the first conductive foil 10, the first conductive foil 10 is partially exposed by patterning. To be more specific, the photoresist 15 is patterned so as to expose portions where the two conductive foils are electrically connected to each other.

Next, as shown in FIG. 4C, the first conductive film 10 is etched through the photoresist 15. Since the first conductive film 10 is mainly made of Cu, chemical etching is performed by use of ferric chloride or cupric chloride as an etchant. A diameter of each of through-holes 17 is varied depending on a resolution of photolithography. Here, the diameter is about 50 to 100 μm.

Next, as shown in FIG. 4D, after the photoresist 15 is removed, the first conductive film 10 is used as a mask, and the insulating film 20A immediately below the through-holes 17 is removed by use of a laser. Accordingly, a rear surface of the second conductive film 11 is exposed to bottoms of the through-holes 17. As the laser, a carbon dioxide laser is applicable. Moreover, if residue remains on the bottoms of the openings after the insulating resin is vaporized by the laser, wet etching is performed by use of sodium permanganate, ammonium persulfate or the like. Thus, the residue is removed.

Next, as shown in FIG. 5A, connection means 16 is formed in the through-holes 17 to electrically connect the first conductive film 10 to the second conductive. film 11. To be more specific, on the entire surface of the first conductive film 10 including the through-holes 17, a plated film is formed, which is the connection means 16 for electrically connecting the second conductive film 11 to the first conductive film 10. This plated film is formed by both nonelectrolytic plating and electrolytic plating. Here, a Cu film having a thickness of about 2 μm is formed by nonelectrolytic plating on the entire surface of the first conductive film 10 including at least the through-holes 17. Thus, the first and second conductive films 10 and 11 are electrically connected to each other. Thereafter, electrolytic plating is performed again by use of the first and second conductive films 10 and 11 as electrodes. Accordingly, Cu of about 20 μm is deposited. Thus, the through-holes 17 are filled with Cu, and the connection means 16 is formed.

Next, as shown in FIGS. 5B to 5D, the first conductive film 10 and the second conductive film 11 are patterned in a desired pattern, and a first conductive pattern 20B and a second conductive pattern 20C are formed. Thus, the laminated sheet 20 is prepared.

1. A circuit module comprising:
a laminated sheet including a first conductive pattern formed on a surface of an insulating film and a second conductive pattern formed on a rear surface of the insulating film;
a pressure sensing element which is electrically connected to the first conductive pattern, and converts a pressure applied from the outside into an electric signal;
a circuit element which is electrically connected to the first conductive pattern and is fixed to a surface of the laminated sheet;
a first reinforcing plate which has a first opening in a spot where the pressure sensing element and the circuit element are provided, and covers the surface of the laminated sheet; and
a second reinforcing plate which has a second opening so as to partially expose the second conductive pattern, and covers a rear surface of the laminated sheet.

2. The circuit module according to claim 1, wherein the laminated sheet, the first and second reinforcing plates have through-holes in substantially the same spots, and the laminated sheet and the first and second reinforcing plates are integrally fastened by use of fastening means penetrating the through-holes.

3. The circuit module according to claim 1, wherein the both reinforcing plates and the laminated sheet are closely attached to each other with insulation sheets interposed therebetween.

4. The circuit module according to claim 1, wherein the first and second reinforcing plates are made of a conductive material.

5. The circuit module according to claim 1, wherein any of the first and second reinforcing plates is connected to a ground potential through the conductive pattern.

6. The circuit module according to claim 1, wherein the second conductive pattern exposed from the second opening functions as an external terminal.

7. The circuit module according to claim 1, wherein the laminated sheet has flexibility.
